(19) United States
(12) Patent Application Publication
(10) Pub. No.: US 2025/0261458 A1
(43) Pub. Date: Aug. 14, 2025

(54) BACKSIDE ILLUMINATED IMAGE SENSOR DEVICE WITH SHIELDING LAYER AND FORMING METHOD

(71) Applicant: TAIWAN SEMICONDUCTOR MANUFACTURING CO., LTD., Hsinchu (TW)

(72) Inventors: Volume CHIEN, Tainan City (TW); Su-Hua CHANG, Chiayi County (TW); Chia-Yu WEI, Tainan City (TW); Zen-Fong HUANG, Tainan City (TW); Chi-Cherng JENG, Tainan City (TW)

(73) Assignee: TAIWAN SEMICONDUCTOR MANUFACTURING CO., LTD., Hsinchu (TW)

(21) Appl. No.: 19/096,968

(22) Filed: Apr. 1, 2025

Related U.S. Application Data
(63) Continuation of application No. 18/360,605, filed on Jul. 27, 2023, now Pat. No. 12,288,798.
Application No. 18/360,605 is a continuation of application No. 17/744,175, filed on May 13, 2022, now Pat. No. 11,810,939.
Application No. 17/744,175 is a division of application No. 14/073,580, filed on Nov. 6, 2013, now Pat. No. 11,335,721.

(51) Int. Cl. H10F 39/12; H10F 39/00; H10F 77/30

(52) U.S. Cl. CPC H10F 39/199; H10F 39/026; H10F 39/8057; H10F 39/8063; H10F 77/334

(57) ABSTRACT

An image sensor includes a pixel array, an interconnect structure, an interconnect structure, a dielectric layer, a plurality of first metal lines and a plurality of second metal lines. The pixel array includes a plurality of photodiodes within a substrate. The interconnect structure is at a front-side of the substrate. The dielectric layer is at a backside of the substrate. The first and second metal lines are disposed on the dielectric layer. The first metal lines extend lengthwise along a first direction. The second metal lines extend lengthwise along a second direction different from the first direction. The first and second metal lines are not connected to each other.

### CROSS-REFERENCES TO RELATED APPLICATION

This application is a continuation application of U.S. patent application Ser. No. 18/360,605, filed Jul. 27, 2023, which is a continuation application of U.S. patent application Ser. No. 17/744,175, filed May 13, 2022, now U.S. Pat. No. 11,810,939, issued on Nov. 7, 2023, which is a divisional application of U.S. patent application Ser. No. 14/073,580 filed Nov. 6, 2013, now U.S. Pat. No. 11,335,721, issued on May 17, 2022, all of which are incorporated herein in their entirety.

### BACKGROUND

### Technical Field

The disclosure generally relates to image sensors, especially CMOS image sensors.

### Description of Related Art

An image sensor provides an array of pixels for recording an intensity or brightness of light. The pixel responds to the light by accumulating a charge. The more light is received, the higher the charge is accumulated. The charge can then be used by another circuit so that information of color and brightness can be used for a suitable application, such as a digital camera. Common types of pixels include a charge-coupled device (CCD) or complementary metal oxide semiconductor (CMOS) image sensor.

Comparing with conventional front-side illuminated (FSI) sensor, backside illuminated (BSI) sensor has been applied on CMOS image sensor to improve the sensitivity of each pixel in the CMOS image sensor. For CMOS image sensor using backside illumination technology, pixels are located on a front side of a substrate, and the substrate is thinned enough to allow light projected on the backside of the substrate to reach the pixels.

However, during the manufacturing process of the BSI sensor, electrostatic charges are often accumulated, and the wafer used can be easily damaged by the accumulated electrostatic charges in a form of arcing to decrease the yield of the BSI sensor.

### BRIEF DESCRIPTION OF THE DRAWINGS

FIGS. 1A-1C are plane diagrams of a backside illuminated image sensor device with a conductive shielding layer according to embodiments of this disclosure.

FIGS. 2A-2C are cross-sectional diagrams showing a manufacturing process of a backside illuminated image sensor device with a conductive shielding layer in FIG. 1A.

FIG. 3 is a flow chart showing the manufacturing process of a backside illuminated image sensor device with a conductive shielding layer in FIGS. 2A-2C.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In the process of manufacturing a backside illuminated image sensor device, it is found that a step of developing a photoresist layer on a dielectric layer can generate electrostatic charge accumulated on the dielectric layer. The accumulated electrostatic charge can induce discharging later in any time to damage the pixel array under the dielectric layer. Accordingly, it is designed to form a conductive shielding layer on the dielectric layer to shielding the structures under the conductive shielding layer from outer applied electric field, which may present in a plasma-assisted deposition step or in a plasma-assisted etching step. Then, the discharging behavior of the accumulated electrostatic charges can be reduced or even be prevented.

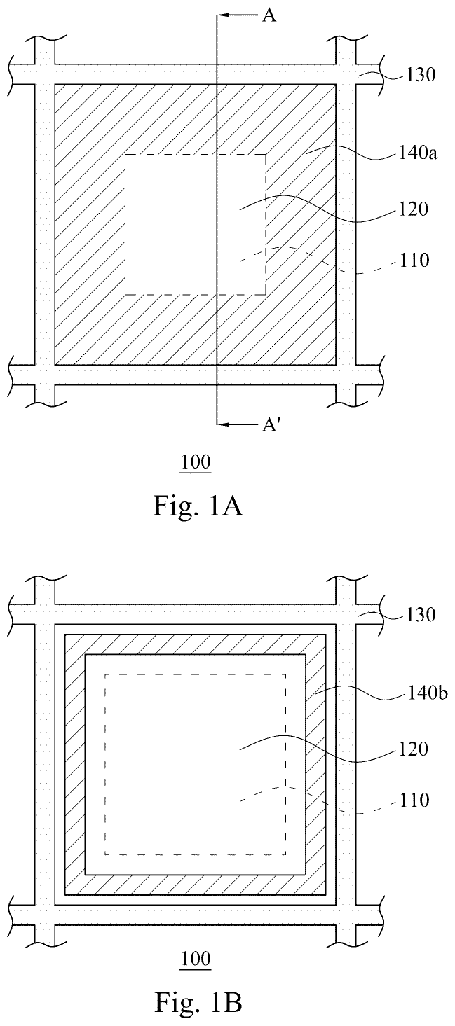

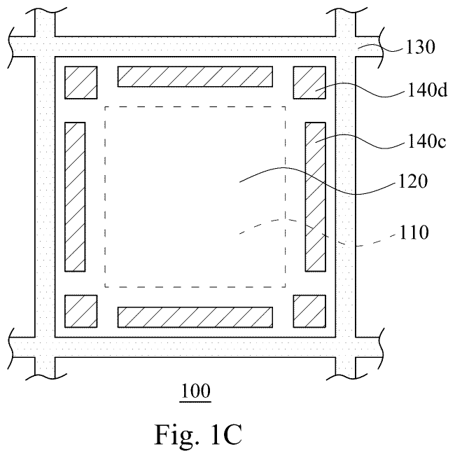

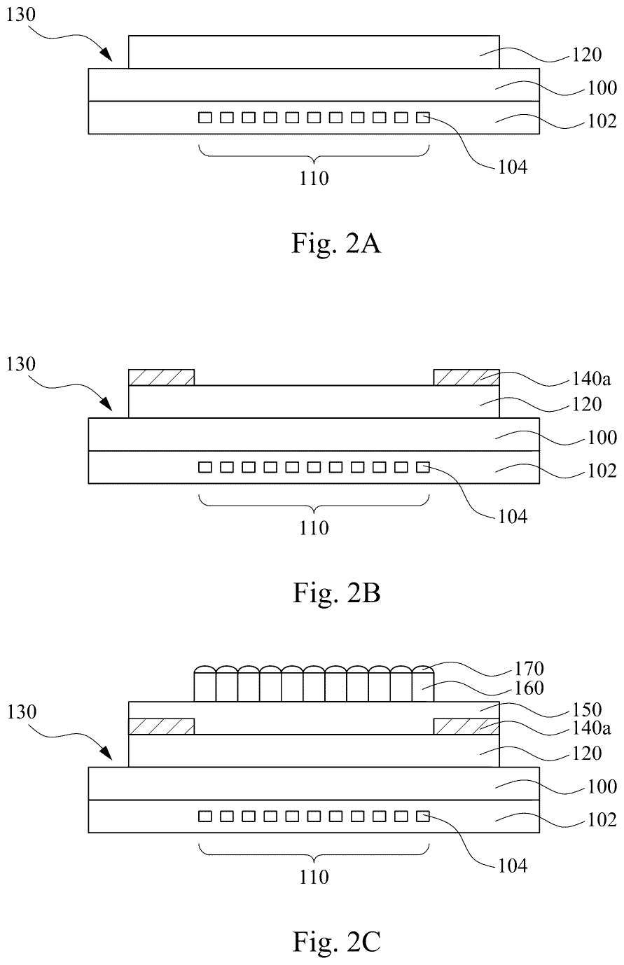

In various embodiments, this disclosure provides a backside illuminated image sensor device with a conductive shielding layer for shielding the structures under the conductive shielding layer from outer applied electric field. FIGS. 1A-1C are plane diagrams of a backside illuminated image sensor device with a conductive shielding layer according to some embodiments of this disclosure. A cross-sectional diagram of the cutting line AA′ is shown in FIG. 2B.

In FIGS. 1A and 2B, a pixel array 110 is disposed on a front surface of a wafer 100. The pixel array 110 includes photodiodes (not shown) in the semiconductor substrate 100 and metal lines 104 in the interconnect layer 102. A dielectric layer 120 is disposed on a back surface of the wafer 100 to cover the backside of the pixel array 110. A plurality of scribe lines 130 are formed in the dielectric layer 120.

A conductive shielding line 140a is disposed on the dielectric layer 120. The conductive shielding line 140a is located on an area between the pixel array 110 and scribe lines 130 and fills the area. Therefore, the conductive shielding line 140a does not stop light irradiating on the pixel array 110 to maximize the light intensity received by the pixel array 110.

In FIG. 1B, the conductive shielding line 140a in FIG. 1A is thinned to the conductive shielding line 140b. However, for maintaining the shielding effect, the line width of the conductive shielding line 140b is at least 300 μm.

The conductive shielding line 140a in FIG. 1A can be further patterned to any patterns as long as the distributed conductive shielding lines is surrounding the pixel array 110 to give protection to the pixel array 110. The shape of the each individual conductive shielding lines viewed from a top direction can be circle, square, polygon, or strip. Still, the narrowest width of the each individual conductive shielding lines is at least 300 μm. For example, the conductive shielding line 140a in FIG. 1A can be patterned to conductive shielding lines 140c in a shape of strip and conductive shielding lines 140d in a shape of square in FIG. 1C.

According to an embodiment of this disclosure, the conductive shielding lines 140a to 140d can be made from a conductive material, such as a metal, a conductive oxide, a conductive polymer, or graphene. The metal can be Al, Cu, Ti, Mo, or a MoCr alloy. The conductive oxide can be AZO (ZnO: Al), GZO (ZnO: Ga), GAZO (ZnO: Ga, Al), ATO (SnO₂: Sb), FTO (SnO₂: F), or ITO (In₂O₃: Sn). The conductive polymer can be poly(3,4-ethylenedioxythiophene) (PEDOT), polyanilines (PANI), or corresponding intrinsically conducting polymers (ICPs).

According to another embodiment of this disclosure, the dielectric layer is made from a dielectric material having a dielectric constant higher than or equal to the dielectric constant of silicon oxide. For example, the dielectric layer can be made from silicon oxide or silicon nitride.

According to another embodiment of this disclosure, the dielectric buffer layer is made from a dielectric material, such as silicon oxide.

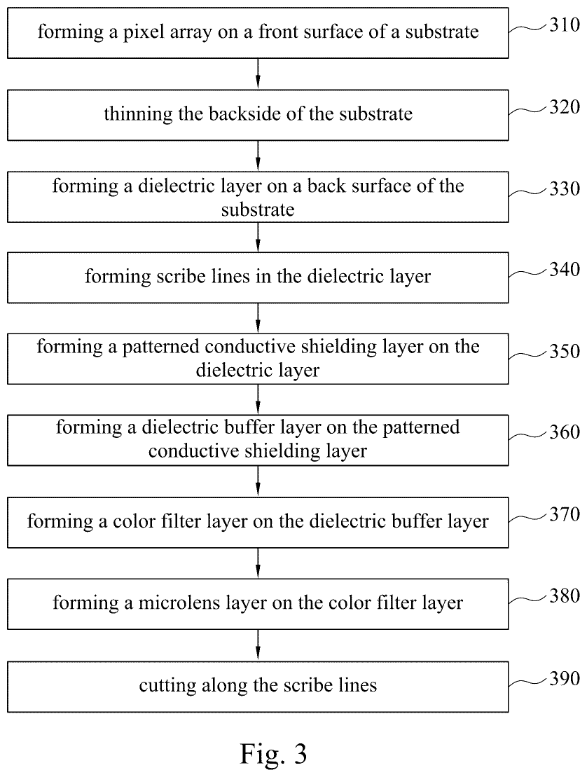

In other embodiments, this disclosure provides a method of manufacturing a backside illuminated image sensor device. The backside illuminated image sensor device with a conductive shielding layer in FIG. 1A is taken as an example. Therefore, FIGS. 2A-2C are cross-sectional diagrams showing a manufacturing process of a backside illuminated image sensor device with a conductive shielding layer in FIG. 1A. In addition, FIG. 3 is a flow chart showing the manufacturing process of a backside illuminated image sensor device with a conductive shielding layer in FIGS. 2A-2C. FIGS. 2A-2C and FIG. 3 are referred hereinafter at the same time.

In FIG. 2A and step 310, the pixel array 110 is formed on the front surface of the semiconductor substrate 100. The pixel array 110 includes photodiodes (not shown) in the semiconductor substrate 100 and metal lines 104 in the interconnect layer 102.

In FIG. 2A and step 320, the backside of the substrate 100 is then thinned to reduce the thickness of the substrate 100 to allow light strike the photodiodes in the substrate 100. Next in step 330, a dielectric layer 120 is formed on the back surface of the substrate 100.

In FIG. 2A and step 340, scribe lines 130 are formed in the dielectric layer 120 by patterning the dielectric layer 120. The method of patterning the dielectric layer 120 can be photolithography and etching. In the step of developing photoresist in the photolithography process, since photoresist and the dielectric layer both are electrically insulating material, friction between two insulating materials often produces electrostatic charges to be accumulated. The accumulated electrostatic charges may damage the pixel array 110 if no prevention or protection treatment is made.

In FIG. 2B and step 350, a conductive shielding line 140a is formed on the dielectric layer 120 to protect the structures under the conductive shielding line 140a from discharging damage. The conductive shielding line 140a can be formed by depositing a conductive shielding layer, and then patterning the conductive shielding layer by a method such as photolithography and etching processes. Since the light received intensity by the photodiodes is better to be maximized, the conductive shielding layer 120 is better not cover the backside of the pixel array 110. However, if the conductive shielding line 140a is transparent to light, the conductive shielding line 140a may cover the backside of the pixel array 110 according to various embodiments of this disclosure.

In FIG. 2C and step 360, a dielectric buffer layer 150 is formed on the conductive shielding line 140a and dielectric layer 120. Next in step 370 and step 380, a color filter layer 160 and a microlens layer 170 are sequentially formed on the dielectric buffer layer 150. Finally, the each individual backside illuminated image sensor is separated from each other by cutting along the scribe lines 130.

According to another embodiment of this disclosure, the conductive shielding lines 140b in FIG. 1B or 140c-140d in FIG. 1C can be formed through different photomask used in the above step of patterning the conductive shielding layer. The other steps are the same as the above-described process, and hence are omitted here.

Accordingly, since at least a conductive shielding line is located on the dielectric layer, any outer applied electric field cannot induce the charging effect of the electrostatic charges accumulated under the conductive shielding layer.

All the features disclosed in this specification (including any accompanying claims, abstract, and drawings) may be replaced by alternative features serving the same, equivalent or similar purpose, unless expressly stated otherwise. Thus, each feature disclosed is one example only of a generic series of equivalent or similar features.

What is claimed is:

1. An image sensor, comprising:
a pixel array comprising a plurality of photodiodes within a substrate;
an interconnect structure at a front-side of the substrate;
a dielectric layer at a backside of the substrate; and
a plurality of first metal lines and a plurality of second metal lines disposed on the dielectric layer, wherein the plurality of first metal lines extend lengthwise along a first direction, the plurality of second metal lines extend lengthwise along a second direction different from the first direction, wherein the plurality of first metal lines and the plurality of second metal lines are not connected to each other.

2. The image sensor of claim 1, further comprising:
a plurality of metal structures disposed on the dielectric layer, wherein in a top view, the plurality of metal structures are adjacent four corners of the pixel array, a length-to-width ratio of one of the plurality of first metal lines and the plurality of second metal lines is greater than a length-to-width ratio of one of the plurality of metal structures.

3. The image sensor of claim 2, wherein the plurality of metal structures are not connected to each other.

4. The image sensor of claim 2, wherein the plurality of metal structures and the plurality of first metal lines are not connected to each other.

5. The image sensor of claim 4, wherein the plurality of metal structures and the plurality of second metal lines are not connected to each other.

6. The image sensor of claim 1, wherein the plurality of first metal lines are disposed adjacent opposite first sides of the pixel array.

7. The image sensor of claim 6, wherein the plurality of second metal lines are disposed adjacent opposite second sides of the pixel array, wherein the second sides connect the first sides of the pixel array.

8. The image sensor of claim 1, wherein the first direction is perpendicular to the second direction.

9. The image sensor of claim 1, further comprising:
a plurality of first scribe line patterns extending lengthwise along the first direction; and
a plurality of second scribe line patterns extending lengthwise along the second direction, wherein the plurality of second scribe line patterns connect the plurality of first scribe line patterns in a top view to form a quadrilateral region, wherein the pixel array is located within the quadrilateral region and spaced apart from the plurality of first scribe line patterns and the plurality of second scribe line patterns by the plurality of first metal lines and the plurality of second metal lines.

10. An image sensor, comprising:
a pixel array comprising a plurality of photodiodes in a semiconductor substrate;
an interconnect structure over the semiconductor substrate;
a dielectric layer spaced apart from the interconnect structure by the semiconductor substrate; and
a plurality of metal structures spaced apart from the semiconductor substrate by the dielectric layer, wherein from a plan view, first ones of the metal structures form first elongated patterns extending lengthwise in a first direction, and second ones of the metal structures form second elongated patterns extending lengthwise in a second direction different than the first direction, wherein the first elongated patterns are discontinuous from the second elongated patterns.

11. The image sensor of claim 10, wherein the plurality of metal structures are formed of Al, Cu, Ti, Mo, or a MoCr alloy.

12. The image sensor of claim 10, wherein the dielectric layer is formed of a dielectric material having a dielectric constant higher than or equal to a dielectric constant of silicon oxide.

13. The image sensor of claim 10, wherein from the plan view, third ones of the metal structures form square patterns disposed adjacent four corners of the pixel array.

14. The image sensor of claim 13, wherein the first elongated patterns and the second elongated patterns have a length-to-width ratio greater than a length-to-width ratio of the square patterns.

15. The image sensor of claim 13, wherein the square patterns are discontinuous from the first elongated patterns.

16. The image sensor of claim 15, wherein the square patterns are discontinuous from the second elongated patterns.

17. A method, comprising:
forming photodiodes in a semiconductor substrate;
forming an interconnect structure over a front-side of the semiconductor substrate;
forming a dielectric layer over a backside of the semiconductor substrate; and
forming a plurality of metal lines over the dielectric layer, the plurality of metal lines non-overlap with the photodiodes, wherein in a plan view, a first sub-set of the plurality of metal lines extend lengthwise in a first direction, a second sub-set of the plurality of metal lines extend lengthwise in a second direction different from the first direction, wherein the first sub-set of the plurality of metal lines and the second sub-set of the plurality of metal lines are disconnected from each other.

18. The method of claim 17, further comprising:
forming a plurality of metal structures over the dielectric layer, wherein in a plan view, the plurality of metal structures has a length-to-width ratio less than a length-to-width ratio of the plurality of metal lines.

19. The method of claim 18, wherein the plurality of metal structures are disconnected from the plurality of metal lines.

20. The method of claim 17, further comprising:
forming a dielectric buffer layer over the plurality of metal lines;
forming a color filter layer over the dielectric buffer layer; and
forming a microlens layer over the color filter layer, wherein the color filter layer and the microlens layer non-overlap with the plurality of metal lines.
